(19) United States
(12) Patent Application Publication
(10) Pub. No.: US 2015/0036329 A1
(43) Pub. Date: Feb. 5, 2015

(54) LIGHT EMITTING MODULE HAVING WAFER WITH INTEGRATED POWER SUPPLY DEVICE

(71) Applicants: Hyuck Jung Choi, Ansan-si (KR); Young Eun Yang, Ansan-si (KR)

(72) Inventors: Hyuck Jung Choi, Ansan-si (KR); Young Eun Yang, Ansan-si (KR)

(73) Assignee: Seoul Semiconductor Co., Ltd., Ansan-si (KR)

(21) Appl. No.: 13/976,653

(22) PCT Filed: Aug. 22, 2011
(86) PCT No.: PCT/KR2011/006173

§ 371 Date: Jul. 31, 2013

(30) Foreign Application Priority Data
Dec. 29, 2010 (KR) 10-2010-0137868

(51) Int. Cl. F21V 23/00; F21L 4/08; H01L 25/16; H01L 33/52; H01L 33/62; H01L 31/02; H01L 31/052; H01L 33/50; F21S 9/03; H01L 25/075

(52) U.S. Cl. CPC F21V 23/005; F21S 9/037; F21L 4/08; H01L 25/167; H01L 25/0753; H01L 33/62; H01L 31/02021; H01L 31/0524; H01L 33/507; H01L 33/52
USPC 362/183; 362/190

(57) ABSTRACT

A light emitting module is disclosed. The light emitting module comprises a wafer having first and second surfaces; a light emitting diode chip disposed on the first surface of the wafer; a power supply device for supplying power to the light emitting diode chip; and a photoelectric conversion device for converting sunlight into electricity and providing it to the power supply device, wherein the power supply device is disposed on the second surface of the wafer.

### CROSS-REFERENCE TO RELATED APPLICATIONS

This application is the National Stage entry of International Application No. PCT/KR2011/006173, filed on Aug. 22, 2011, and claims priority from and the benefit of Korean Application No. 10-2010-0137868, filed on Dec. 29, 2010, which are hereby incorporated by reference as if fully set forth herein.

### BACKGROUND

### Field

The present invention relates to a light emitting module having a light emitting diode chip, and more particularly, to a light emitting module configured by integrating a power supply device and one or more light emitting diode chips on one wafer.

### Discussion of the Background

A light emitting diode is a representative semiconductor light emitting device that emits light through recombination of electrons and holes between n-type and p-type semiconductor layers when current is applied thereto. A light emitting diode has many advantages of continuous light emission using low voltage and low current, small electric power consumption, and the like, as compared with a conventional light source.

Generally, a light emitting diode package fabricated by mounting one or more light emitting diode chips to a package is frequently used. The light emitting diode package comprises a package body, which is mounted with lead frames corresponding to the light emitting diode chip. The lead frames and the light emitting diode chip are electrically connected by a wire(s), and thus, the light emitting diode chip that receives electric power applied from the outside can generate light.

Recently, there has been developed a light emitting module fabricated by mounting a light emitting diode chip on a wafer such as a silicon wafer, and the light emitting module is referred to as a ‘wafer-level package.’

### SUMMARY

A conventional light emitting module has a disadvantage in that a light emitting diode chip on a wafer should operate depending on an external AC power source or a battery. Since the light emitting module always operates depending on conditions of the external power source, there is a limitation in using the light emitting module in a power failure or another emergency situation.

In a fabrication method of the conventional light emitting module, a plurality of light emitting diode chips are mounted on a front surface of a wafer, but the applicability of a rear surface of the wafer is considerably lowered. A via or electrode extending to the rear surface of the wafer is used as a terminal. Otherwise, the rear surface of the wafer is hardly utilized.

Meanwhile, a method of mounting light emitting diode chips on one large-sized wafer, performing wire connection and then cutting the wafer into a plurality of pieces is used as an example of a conventional fabrication method of a wafer-level package or light emitting module. It has been known that the method has a high productivity as compared with other conventional fabrication methods of a light emitting diode package. However, all components such as a power supply device and the like, which participate in the operation of a light emitting diode chip, are still separately assembled for each light emitting module.

Accordingly, an object of the present invention is to provide a light emitting module, in which light emitting diode chips are disposed on a first surface of a wafer, and a power supply device such as a capacitor or secondary battery is integrated on a second surface opposite to the first surface, thereby increasing the applicability of the surfaces of the wafer.

Another object of the present invention is to provide a light emitting module, in which light emitting diode chips are disposed on a first surface of a wafer, a power supply device such as a capacitor or secondary battery is integrated on a second surface opposite to the first surface, and a photoelectric conversion device for converting sunlight into electricity is additionally provided, so that the photoelectric conversion device and the power supply device allow the light emitting module not to use external power or to use only minimum external power.

A light emitting module according to an aspect of the present invention comprises a wafer having first and second surfaces; a light emitting diode chip disposed on the first surface of the wafer; a power supply device for supplying power to the light emitting diode chip; and a photoelectric conversion device for converting sunlight into electricity and providing it to the power supply device, wherein the power supply device is disposed on the second surface of the wafer. Preferably, the first and second surfaces are opposite to each other.

In detailed descriptions and claims, the first surface of the wafer means a surface on which one or more light emitting diode chips are mounted, and the second surface of the wafer means any surface different from the first surface.

According to one embodiment, the power supply device may be a capacitor, secondary battery, or fuel cell. The power supply device may comprise an anode layer, a cathode layer and a solid electrolyte interposed between these layers. In such a case, insulation films may be formed on one surface of the power supply device, which is in contact with the wafer, and an opposite surface of the power supply device, respectively.

According to one embodiment, the light emitting module may further comprise a lens or light guide for condensing sunlight to the photoelectric conversion device.

According to one embodiment, the photoelectric conversion device may be mounted to be in contact with the first or second surface of the wafer.

A light emitting module according to another aspect of the present invention comprises a wafer having first and second surfaces; a plurality of light emitting diode chips disposed on the first surface of the wafer; and a power supply device for supplying power to the plurality of light emitting diode chips, wherein the power supply device is disposed on the second surface of the wafer.

According to one embodiment, the power supply device may be a capacitor, secondary battery, or fuel cell. Furthermore, the power supply device may comprise an anode layer, a cathode layer and a solid electrolyte interposed between these layers. Insulation films may be formed on one surface of the power supply device, which is in contact with the wafer, and an opposite surface of the power supply device, respectively.

According to one embodiment, the light emitting module may further comprise a photoelectric conversion device for converting sunlight into electricity and providing it to the power supply device.

There are provided a plurality of the photoelectric conversion devices, wherein the plurality of photoelectric conversion devices may be disposed to surround a periphery of the power supply device or to surround a periphery of the light emitting diode chips.

Preferably, the plurality of photoelectric conversion devices are connected in series.

Preferably, at least two of the plurality of light emitting diode chips are connected in series or parallel.

The light emitting module may further comprise a transparent encapsulant for individually or entirely encapsulating the plurality of light emitting diode chips, and a phosphor positioned in the inside of the encapsulant or between the encapsulant and the light emitting diode chip.

Preferably, the light emitting module may further comprise an optical sensor for measuring external brightness, and a controller for controlling turning on and off of the light emitting diode chips based on information on the brightness provided from the optical sensor.

Preferably, the light emitting module may further comprise a voltage/current variable circuit.

In the light emitting module according to the present invention, light emitting diode chips are disposed on a first surface of a wafer, and a power supply device is disposed on a second surface opposite to the first surface, thereby improving the surface applicability of the wafer. Further, there is an advantage in that the light emitting module can remove or minimize use of an external power source.

A large number of wafer-level packages or light emitting modules can be fabricated by cutting a large-sized wafer having a large number of light emitting diode chips disposed thereon into a plurality of pieces. In this case, a large number of power supply devices are disposed on a second surface of the large-sized wafer, and the large-sized wafer is then cut into the plurality of pieces, so that the wafer-level package or light emitting module with the integrated light emitting diode chip and power supply device can be easily, rapidly and inexpensively fabricated. This mainly results from a decrease in the number of fabricating processes.

A photoelectric conversion device for converting sunlight into electricity is added to the aforementioned wafer-level package or light emitting module, so that the light emitting diode chip can be operated without external power or by minimally using external power.

### BRIEF DESCRIPTION OF THE DRAWINGS

FIG. 1 is a sectional view showing a light emitting module according to an embodiment of the present invention;

FIG. 2 is an enlarged sectional view showing circle A of FIG. 1;

FIG. 3 is an enlarged sectional view showing ellipse B of FIG. 1;

FIG. 4 is a view showing an example of an arrangement of photoelectric conversion devices in the light emitting module shown in FIG. 1;

FIG. 5 is a sectional view showing a light emitting module according to another embodiment of the present invention.

FIGS. 6 (a) to (c) are sectional views showing light emitting modules having various types of encapsulants according to the present invention;

FIGS. 7a to 7c are sectional views showing light emitting modules having various types of light condensing means according to the present invention; and

FIG. 8 is a block diagram showing an example of an illumination device comprising the light emitting module shown in FIGS. 1 to 7c.

### DETAILED DESCRIPTION OF THE ILLUSTRATED EMBODIMENTS

Hereinafter, preferred embodiments of the present invention will be described in detail with reference to the accompanying drawings. The following embodiments are provided only for illustrative purposes so that those skilled in the art can fully understand the spirit of the present invention. Therefore, the present invention is not limited to the following embodiments but may be implemented in other forms. In the drawings, the widths, lengths, thicknesses and the like of elements may be exaggerated for convenience of illustration. Like reference numerals indicate like elements throughout the specification and drawings.

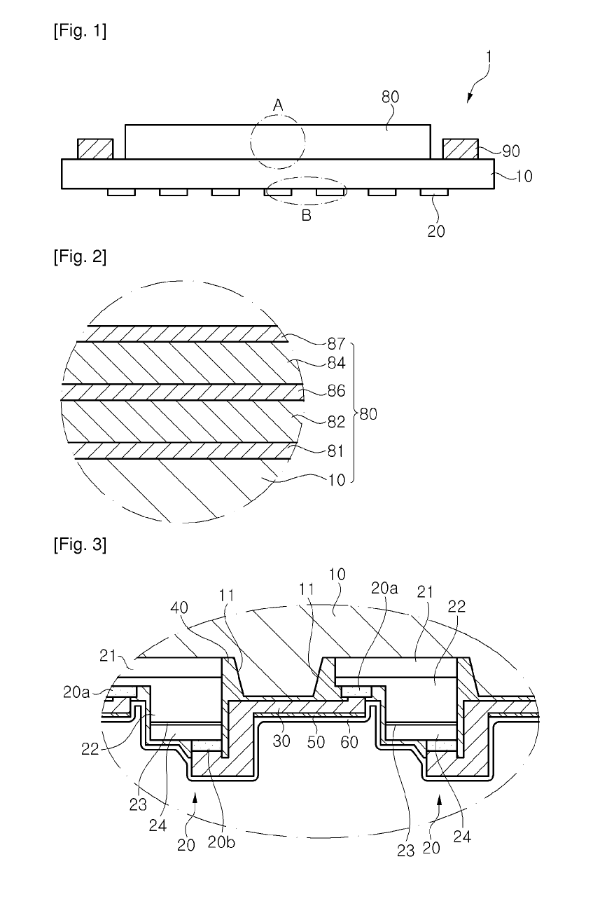

FIG. 1 is a sectional view showing a light emitting module according to an embodiment of the present invention.

Referring to FIG. 1, a light emitting module 1 according to the embodiment of the present invention comprises a wafer 10, a plurality of light emitting diode chips 20 disposed on a front surface of the wafer 10, and a power supply device 80 disposed on a rear surface of the wafer 10. The wafer 10 is preferably a silicon (Si) wafer. However, wafers made of other materials such as Al₂O₃, SiC, ZnO, GaAs, GaP, Bn, LiAl₂O₃, AlN and GaN may be used as the wafer 10.

The light emitting diode chip 20 is preferably made of a Group-III nitride compound semiconductor.

The power supply device 80 is a device that can store and supply electric energy, and may be, for example, a capacitor, secondary battery, fuel cell, or the like.

According to a preferred embodiment, the power supply device 80 may comprise an anode layer 82, a cathode layer 84, and a solid electrolyte 86 interposed between these layers, as shown in FIG. 2. A first insulation film 81 is formed on one surface of the power supply device that is in contact with the wafer 10, and a second insulation film 87 is formed on an opposite surface of the power supply device. The first insulation film 81 is provided to insulate the power supply device 80 from a portion of a via or electrode (not shown) that may be formed on the rear surface of the wafer 10. The second insulation film 87 is provided to insulate the power supply device 80 from other electric circuits or electric components disposed in a periphery of the power supply device.

Although not shown, the wafer 10 is provided with a power source or power path for supplying power of the power supply device 80 to the light emitting diode chips 20, and the power source or power path may be provided with a voltage/current variable circuit.

Referring back to FIG. 1, the light emitting module 1 comprises a plurality of photoelectric conversion devices 90 for converting sunlight from the outside into electricity and providing it to the power supply device 80. The photoelectric conversion devices 90 are preferably integrated into the wafer 10, but may be disposed to be spaced apart from the wafer 10. In this case, the photoelectric conversion devices 90 may be supported by a portion of the light emitting module other than the wafer 10, e.g., a housing (not shown) of the light emitting module 1, or the like.

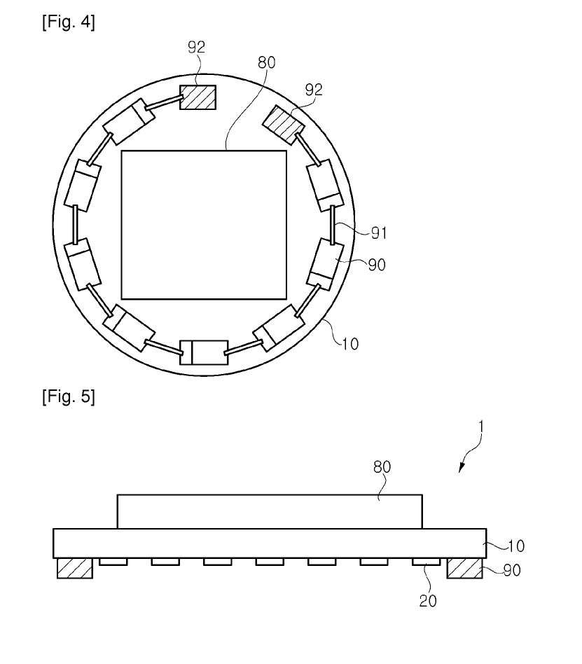

Referring to FIG. 4, the plurality of photoelectric conversion devices 90 are disposed on the rear surface of the wafer 10 to surround the periphery of the power supply device 80. The plurality of photoelectric conversion devices 90 are connected in series by wires 91 so as to improve photoelectric conversion efficiency. A pair of terminal pads 92 are installed at both ends of an array of the photoelectric conversion devices 90, respectively. The photoelectric conversion device 90 is preferably made of a Group III-V semiconductor compound.

Referring to FIG. 3, the light emitting chips 20 mounted on the wafer 10 are enlarged and shown. The structure, shape and arrangement of the light emitting diode chips 20 shown in FIG. 3 is a preferred embodiment of the present invention. However, it is noted that if one or more of the light emitting diode chips 20 are disposed on the front surface of the wafer 10, the structure, shape and arrangement of the light emitting diode chips 20 may be variously changed or modified within the technical scope of the present invention.

According to a preferred embodiment, grooves 11 are formed in the front surface of the wafer 10, and the light emitting diode chips 20 are mounted on the wafer 10 so that lower portions of the light emitting diode chips are partially disposed in the grooves 11, respectively.

The light emitting diode chip 20 comprises a substrate 21, and a first conductive semiconductor layer 22, an active layer 23 and a second conductive semiconductor layer 24, which are laminated on the substrate 21. The substrate 21 may be a growth substrate for growing these layers made of a compound semiconductor, and the growth substrate is preferably a sapphire substrate suitable for the growth of a Group-III nitride semiconductor. In case of a light emitting diode chip having a sapphire substrate as the growth substrate 21, the first conductive semiconductor layer 22 may be an n-type compound semiconductor layer, and the second conductive semiconductor layer 24 may be a p-type compound semiconductor layer. Although shown, a transparent electrode layer or current diffusion layer such as an ITO layer may be formed on the second conductive semiconductor layer 24.

The first conductive semiconductor layer 22, the active layer 23 and the second conductive semiconductor layer 24 may be formed of a Group-III nitride compound semiconductor, e.g., an (Al, Ga, In)N semiconductor. Each of the first and second conductive semiconductor layers 22 and 24 may be formed to have a single or multiple layer structure. For example, the first conductive semiconductor layer 22 and/or the second conductive semiconductor layer 24 may comprise contact and clad layers, and may further comprise a superlattice layer. Also, the active layer 23 may be formed to have a single or multiple quantum well structure.

In this embodiment, a partial region of the first conductive semiconductor layer 22 is exposed by partially removing the second conductive semiconductor layer 24 and the active layer 23. A first conductive electrode pad 20a is formed on the exposed first conductive semiconductor layer 22, and a second conductive electrode pad 20b is formed on the second conductive semiconductor layer 24.

Meanwhile, an insulation film 40 is formed on the front surface of the wafer 10 so as to entirely cover the light emitting diode chips 20 except the electrode pads 20a and 20b. In addition, the insulation film 40 covers not only the light emitting diode chips 20 but also the front surface of the wafer 10 in a periphery of the light emitting diode chips 20. The insulation film 40 serves to insulate an electrode film 30 and the light emitting diode chips 20 from each other. Furthermore, the insulation film serves to insulate the semiconductor layers from each other at side surfaces of the light emitting diode chip 20. Particularly, the insulation film 40 becomes a base layer for the electrode film 30, a reflection film 50 and a protection film 60. Thus, the insulation film 40 also serves to variously adjust the heights of these films with respect to the light emitting diode chip 20 or its corresponding semiconductor layers, particularly the active layer, by changing the thickness of the insulation film 40. The insulation film 40 is preferably formed of SiO₂ or an insulative material containing SiO₂ as a major component.

In the front surface of the wafer 10, regions of the insulation film 40, in which the first and second conductive electrode pads 20a and 20b of the light emitting diode chips 20 exist, are removed, and therefore, the first and second conductive electrode pads 20a and 20b are exposed from the insulation film 40. The electrode film 30 described above is regionally formed on the insulation film 40, to electrically connect the first and second electrode pads 20a and 20b of the adjacent light emitting diode chips to each other.

The electrode film 30 is preferably formed of a metal material having excellent electric conductivity. More preferably, the electrode film is formed of at least one metal material of Au, Cu and Al, or an alloy material containing the metal material.

The reflection film 50 for reflecting upward the light emitted from the side surfaces of the adjacent light emitting diode chips 20 is formed to cover at least a part of the electrode film 30 between the light emitting diode chips 20. Although not specifically shown, the reflection film 50 may be formed to have a width greater than that of the electrode film 30. In this case, a part or most of the reflection film 50 is positioned on the insulation film 40 while being in direct contact with the insulation film. At this time, the reflection film 50 is preferably positioned lower than the active layer 23 of the light emitting diode chip 20. The reflection film 50 positioned below the active layer 23 more effectively reflects the light, which is generated from the active layer 23 and then emitted to the side surface of the light emitting diode chip 20, so that the light can be guided in a desired direction. The reflection film 50 is preferably formed of a metal material having excellent reflexibility. More preferably, the reflection film 50 is formed of at least one metal material of Ag, Au and Ni, or an alloy material containing the metal material. Finally, the protection film 60 is provided to entirely cover the reflection film 50, the electrode film 30, the insulation film 40 and the light emitting diode chips 20.

Although not shown, separate electrodes or electrode pads (not shown) may be further formed together with the light emitting diode chips 20 on the front surface of the wafer 10. The electrodes or electrode pads may be connected to a conducting portions (not shown) such as vias, which are continued from the front surface of the wafer 10 to the rear surface thereof.

FIG. 5 shows a sectional view of a light emitting module according to another embodiment of the present invention. Referring to FIG. 5, in a light emitting module 1 according to this embodiment, a plurality of photoelectric conversion devices 90 together with light emitting diode chips 20 are disposed on a front surface of a wafer 10. The plurality of photoelectric conversion devices 90 are preferably connected in series while being disposed to surround a periphery of the light emitting diode chips 20. Like the aforementioned embodiment, a power supply device is disposed on a rear surface of the wafer 10.

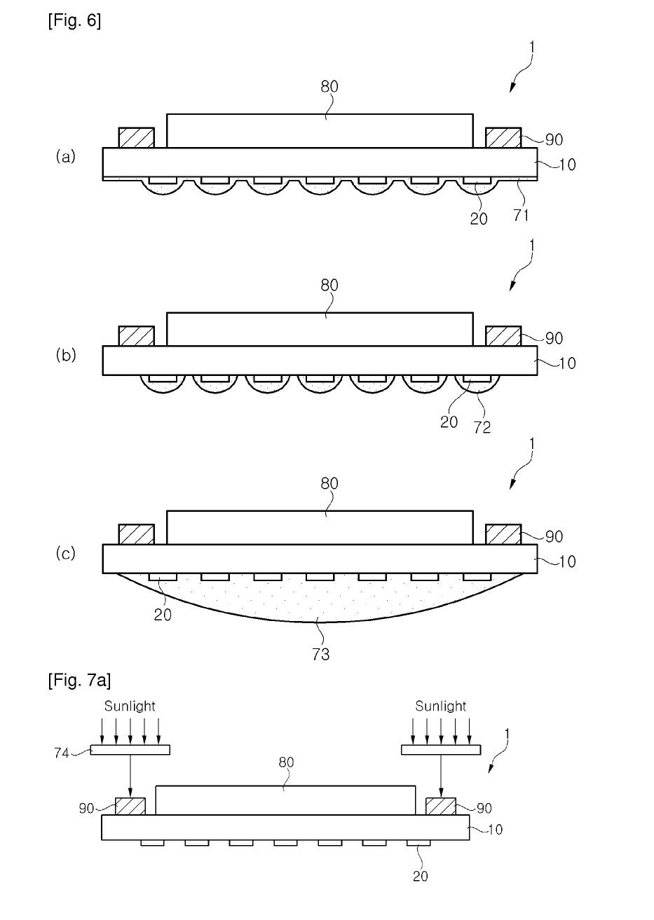

In FIGS. 6 (a), (b) and (c), an encapsulant 71, 72 or 73 for protecting the light emitting diode chips 20 disposed on the front surface of the wafer 10 is shown together with the light emitting diode chips. As shown in FIGS. 6 (a) and (c), the single encapsulant 71 or 73 may be formed to cover all the light emitting diode chips 20 disposed on the front surface of the wafer 10. The encapsulant 71 shown in FIG. 6 (a) has a plurality of lens shapes corresponding to the respective light emitting diode chips 20. Meanwhile, as shown in FIG. 6 (b), a plurality of encapsulants 72 may be formed to individually cover the light emitting diode chips 20. Phosphors for generating white light, for example, may be contained in the inside of the encapsulant 71, 72 or 73, or between the light emitting diode chips 20 and the encapsulant 71, 72 or 73.

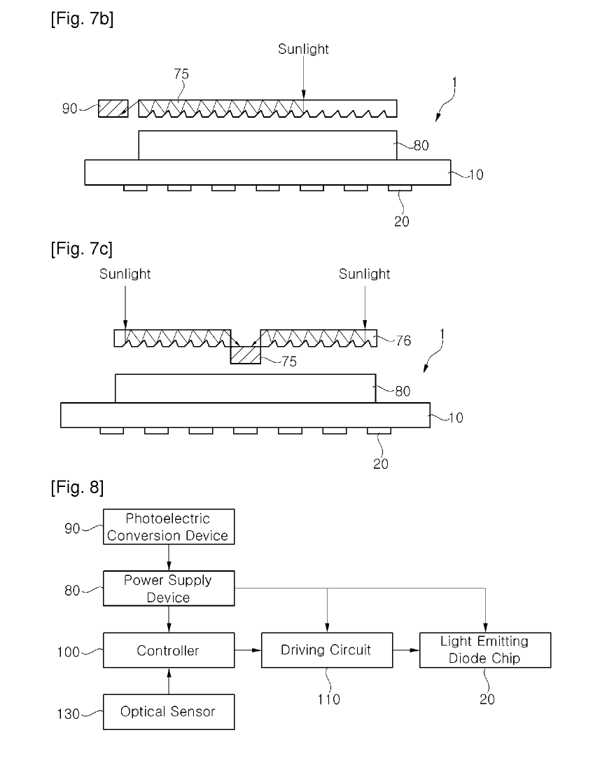

FIGS. 7a to 7c show light condensing means for condensing light to the photoelectric conversion device 90.

Referring to FIG. 7a, a light condensing lens 74 such as a Fresnel lens is used as the light condensing means. In this case, sunlight passes through the light condensing lens 74 and is then condensed toward the photoelectric conversion device 90 disposed below the light condensing lens.

Referring to FIGS. 7b and 7c, a light guide 75 or 76 is used as the light condensing means. In this case, sunlight is incident through an upper incident surface of the light guide 75 or 76. The light entering the light guide 75 or 76 moves inside of the light guide 75 or 76, exits from the light guide 75 or 76 through a side surface of the light guide 75 or an exiting surface positioned in a hollow at the center of the light guide 76, and then enters the photoelectric conversion device 90.

For example, a prism pattern, hologram pattern or the like may be formed in a bottom surface of the light guide 75 or 76 in order to smoothly guide the light.

In FIG. 7c, prism patterns having a plurality of concentric circles having different diameters about a hollow of the light guide 76 are formed in a bottom surface of the light guide 76. The photoelectric conversion device 90 is disposed near the hollow of the light guide. In this case, the light incident on a portion distant from the center of the light guide moves to the vicinity of the hollow in which the photoelectric conversion device 90 is disposed and then enters the photoelectric conversion device 90.

FIG. 8 is a block diagram showing an example of an illumination device comprising the aforementioned light emitting module.

The illumination device shown in FIG. 8 comprises the light emitting diode chip 20, the power supply device 80 and the photoelectric conversion device 90, which are described above, and a controller 100, a driving circuit 110 and an optical sensor 130. Electric power generated by the photoelectric conversion device 90 is provided and stored in the power supply device 80, and electricity of the power supply device 80 is used to operate the controller 100, the driving circuit 110 and the light emitting diode chips 120. The optical sensor 130 measures brightness at the installation position of the illumination device and provides the measured brightness as a signal to the controller 100. The controller 100 then controls the driving circuit 110 based on the information on the external brightness provided from the optical sensor 130, and turns on and off the light emitting diode chips 20 according to whether the surroundings of the illumination device are bright or dark. The illumination device may comprise a current/voltage variable circuit and an ESD protection circuit.

1. A light emitting module, comprising:
a wafer comprising a first surface and an opposing second surface;
a light emitting diode chip disposed on the first surface of the wafer;
a power supply device configured to supply power to the light emitting diode chip, the power supply device disposed on the second surface of the wafer; and
a photoelectric conversion device configured to convert sunlight into electricity and to provide the electricity to the power supply device.

2. The light emitting module of claim 1, wherein the power supply device comprises a capacitor, a secondary battery, or a fuel cell.

3. The light emitting module of claim 1, wherein the power supply device comprises an anode layer, a cathode layer, and a solid electrolyte disposed therebetween.

4. The light emitting module of claim 1, further comprising a lens or light guide configured to condense light onto the photoelectric conversion device.

5. The light emitting module of claim 1, wherein the photoelectric conversion device is disposed directly on the first or second surface of the wafer.

6. The light emitting module of claim 1, further comprising first and second insulation films disposed on a first surface of the power supply device that faces the wafer, and an opposing second surface of the power supply device, respectively.

7. A light emitting module, comprising:
a wafer comprising a first surface and an opposing second surface;
light emitting diode chips disposed on the first surface of the wafer; and
a power supply device configured to supply power to the light emitting diode chips,
wherein the power supply device is disposed on the second surface of the wafer.

8. The light emitting module of claim 7, wherein the power supply device comprises a capacitor, a secondary battery, or a fuel cell.

9. The light emitting module of claim 7, wherein the power supply device comprises an anode layer, a cathode layer, and a solid electrolyte interposed therebetween.

10. The light emitting module of claim 7, further comprising a photoelectric conversion device configured to convert sunlight into electricity and to provide the electricity to the power supply device.

11. The light emitting module of claim 7, further comprising photoelectric conversion devices configured to convert sunlight into electricity and to provide the electricity to the power supply device, wherein the photoelectric conversion devices surround the power supply device.

12. The light emitting module of claim 7, further comprising photoelectric conversion devices configured to convert sunlight into electricity and to provide the electricity to the power supply device, wherein the photoelectric conversion devices surround the light emitting diode chips.

13. The light emitting module of claim 11, wherein the photoelectric conversion devices are connected in series.

14. The light emitting module of claim 7, wherein at least two of the light emitting diode chips are connected in series or parallel.

15. The light emitting module of claim 7, further comprising a transparent encapsulant disposed on the light emitting diode chips, and a phosphor disposed inside the encapsulant, or between the encapsulant and the light emitting diode chip.

16. The light emitting module of claim 7, further comprising an optical sensor configured to measure an external brightness, and a controller configured to turn the light emitting diode chips on and off based on the brightness measured by the optical sensor.

17. The light emitting module of claim 7, further comprising a voltage/current variable circuit.

18. The light emitting module of claim 7, further comprising first and second insulation films disposed on a first surface of the power supply device that faces the wafer, and an opposing second surface of the power supply device, respectively.
